(19) United States
(12) Patent Application Publication
(10) Pub. No.: US 2008/0303015 A1
(43) Pub. Date: Dec. 11, 2008

(54) MEMORY HAVING SHARED STORAGE MATERIAL

(76) Inventors: Thomas Happ, Tarrytown, NY (US); Jan Boris Philipp, Peekskill, NY (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/759,467

(22) Filed: Jun. 7, 2007

(51) Int. Cl. H01L 29/06; H01L 21/00

(52) U.S. Cl. 257/5; 438/102; 257/E29.005; 257/E21.001

(57) ABSTRACT

An integrated circuit includes a bit line and a plurality of access devices coupled to the bit line. The integrated circuit includes a plate of phase change material and a plurality of contacts. Each contact is coupled to an access device and contacting the plate of phase change material. A phase change element is formed at each intersection of a contact and the plate of phase change material.

### CROSS-REFERENCE TO RELATED APPLICATIONS

This Utility patent application is related to U.S. patent application Ser. No. ##/###,###, Attorney Docket Number I331.321.101, entitled “MEMORY HAVING SHARED STORAGE MATERIAL,” filed on the same date as the present application, and which is incorporated herein by reference.

### BACKGROUND

One type of memory is resistive memory. Resistive memory utilizes the resistance value of a memory element to store one or more bits of data. For example, a memory element programmed to have a high resistance value may represent a logic “1” data bit value, and a memory element programmed to have a low resistance value may represent a logic “0” data bit value. The resistance value of the memory element is switched electrically by applying a voltage pulse or a current pulse to the memory element. One type of resistive memory is phase change memory. Phase change memory uses a phase change material for the resistive memory element.

Phase change memories are based on phase change materials that exhibit at least two different states. Phase change material may be used in memory cells to store bits of data. The states of phase change material may be referred to as amorphous and crystalline states. The states may be distinguished because the amorphous state generally exhibits higher resistivity than does the crystalline state. Generally, the amorphous state involves a more disordered atomic structure, while the crystalline state involves a more ordered lattice. Some phase change materials exhibit more than one crystalline state, e.g. a face-centered cubic (FCC) state and a hexagonal closest packing (HCP) state. These two crystalline states have different resistivities and may be used to store bits of data. In the following description, the amorphous state generally refers to the state having the higher resistivity, and the crystalline state generally refers to the state having the lower resistivity.

Phase change in the phase change materials may be induced reversibly. In this way, the memory may change from the amorphous state to the crystalline state and from the crystalline state to the amorphous state in response to temperature changes. The temperature changes to the phase change material may be achieved by driving current through the phase change material itself, or by driving current through a resistive heater adjacent the phase change material. With both of these methods, controllable heating of the phase change material causes controllable phase change within the phase change material.

A phase change memory including a memory array having a plurality of memory cells that are made of phase change material may be programmed to store data utilizing the memory states of the phase change material. One way to read and write data in such a phase change memory device is to control a current and/or a voltage pulse that is applied to the phase change material. The level of current and/or voltage generally corresponds to the temperature induced within the phase change material in each memory cell.

To achieve higher density phase change memories, a phase change memory cell can store multiple bits of data. Multi-bit storage in a phase change memory cell can be achieved by programming the phase change material to have intermediate resistance values or states. If the phase change memory cell is programmed to one of three different resistance levels, 1.5 bits of data per cell can be stored. If the phase change memory cell is programmed to one of four different resistance levels, two bits of data per cell can be stored, and so on.

During fabrication of phase change memory cells, phase change material is typically etched to form storage locations. Etching phase change material, however, may damage the edges of the phase change material and may be difficult to control. The impact of the damaged phase change material increases as the critical dimension of the phase change memory cells is reduced. As the critical dimension of the phase change memory cells is reduced, the damaged phase change material includes a larger percentage of the storage location. If the percentage of damaged phase change material is too large, the phase change memory cell may not function properly.

For these and other reasons, there is a need for the present invention.

### SUMMARY

One embodiment provides an integrated circuit. The integrated circuit includes a bit line and a plurality of access devices coupled to the bit line. The integrated circuit includes a plate of phase change material and a plurality of contacts. Each contact is coupled to an access device and contacting the plate of phase change material. A phase change element is formed at each intersection of a contact and the plate of phase change material.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a diagram illustrating one embodiment of an array of phase change memory cells.

FIG. 2 illustrates a top view of one embodiment of an array of phase change memory cells.

FIG. 3A illustrates a simplified side view of one embodiment of an array of phase change memory cells.

FIG. 3B illustrates a simplified side view of another embodiment of an array of phase change memory cells.

FIG. 4 illustrates a top cross-sectional view of one embodiment of a ring contact.

FIG. 5 is a diagram illustrating another embodiment of an array of phase change memory cells.

FIG. 6A illustrates a top view of one embodiment of an array of phase change memory cells including a plate of phase change material.

FIG. 6B illustrates a top view of another embodiment of an array of phase change memory cells including a plate of phase change material.

FIG. 6C illustrates a top view of another embodiment of an array of phase change memory cells including a plate of phase change material.

FIG. 7A illustrates a top view of another embodiment of an array of phase change memory cells including a plate of phase change material.

FIG. 7B illustrates a top view of another embodiment of an array of phase change memory cells including a plate of phase change material.

FIG. 7C illustrates a top view of another embodiment of an array of phase change memory cells including a plate of phase change material.

FIG. 8A illustrates a top view of one embodiment of an array of phase change memory cells including several mini-plates of phase change material.

FIG. 8B illustrates a top view of another embodiment of an array of phase change memory cells including several mini-plates of phase change material.

FIG. 8C illustrates a top view of another embodiment of an array of phase change memory cells including several mini-plates of phase change material.

FIG. 9A illustrates a top view of another embodiment of an array of phase change memory cells including several mini-plates of phase change material.

FIG. 9B illustrates a top view of another embodiment of an array of phase change memory cells including several mini-plates of phase change material.

FIG. 9C illustrates a top view of another embodiment of an array of phase change memory cells including several mini-plates of phase change material.

FIG. 10A illustrates a simplified side view of one embodiment of an array of phase change memory cells including a plate of phase change material.

FIG. 10B illustrates a simplified side view of one embodiment of an array of phase change memory cells including a plate of phase change material.

FIG. 10C illustrates a simplified side view of one embodiment of an array of phase change memory cells including a plate of phase change material.

FIG. 11A illustrates a simplified side view of another embodiment of an array of phase change memory cells including a plate of phase change material.

FIG. 11B illustrates a simplified side view of another embodiment of an array of phase change memory cells including a plate of phase change material.

FIG. 11C illustrates a simplified side view of another embodiment of an array of phase change memory cells including a plate of phase change material.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

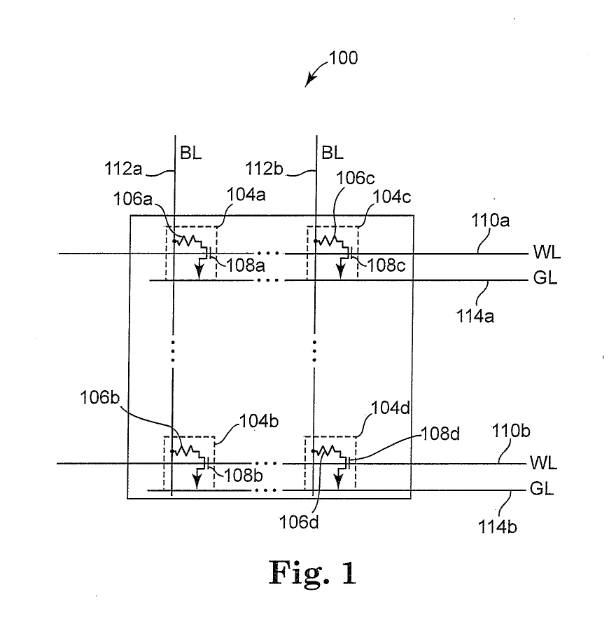

FIG. 1 is a diagram illustrating one embodiment of an array of phase change memory cells 100. Memory array 100 includes a plurality of phase change memory cells 104a-104d (collectively referred to as phase change memory cells 104), a plurality of bit lines (BLs) 112a-112b (collectively referred to as bit lines 112), a plurality of word lines (WLs) 110a-110b (collectively referred to as word lines 110), and a plurality of ground lines (GLs) 114a-114b (collectively referred to as ground lines 114). Memory array 100 also includes a plurality of lines of phase change material, each line of phase change material aligned with, contacting, and running along a bit line 112.

As used herein, the term “electrically coupled” is not meant to mean that the elements must be directly coupled together and intervening elements may be provided between the “electrically coupled” elements.

Each phase change memory cell 104 is electrically coupled to a word line 110, a bit line 112, and a ground line 114. For example, phase change memory cell 104a is electrically coupled to bit line 112a, word line 110a, and ground line 114a, and phase change memory cell 104b is electrically coupled to bit line 112a, word line 110b, and ground line 114b. Phase change memory cell 104c is electrically coupled to bit line 112b, word line 110a, and ground line 114a, and phase change memory cell 104d is electrically coupled to bit line 112b, word line 110b, and ground line 114b.

Each phase change memory cell 104 includes a phase change element 106 and a transistor 108. While transistor 108 is a field-effect transistor (FET) in the illustrated embodiment, in other embodiments, transistor 108 can be other suitable devices such as a bipolar transistor or a 3D transistor structure. Phase change memory cell 104a includes phase change element 106a and transistor 108a. One side of phase change element 106a is electrically coupled to bit line 112a through a line of phase change material running along bit line 112a, and the other side of phase change element 106a is electrically coupled to one side of the source-drain path of transistor 108a. The other side of the source-drain path of transistor 108a is electrically coupled to ground line 114a. The gate of transistor 108a is electrically coupled to word line 110a.

Phase change memory cell 104b includes phase change element 106b and transistor 108b. One side of phase change element 106b is electrically coupled to bit line 112a through the line of phase change material running along bit line 112a, and the other side of phase change element 106b is electrically coupled to one side of the source-drain path of transistor 108b. The other side of the source-drain path of transistor 108b is electrically coupled to ground line 114b. The gate of transistor 108b is electrically coupled to word line 110b.

Phase change memory cell 104c includes phase change element 106c and transistor 108c. One side of phase change element 106c is electrically coupled to bit line 112b through a line of phase change material running along bit line 112b, and the other side of phase change element 106c is electrically coupled to one side of the source-drain path of transistor 108c. The other side of the source-drain path of transistor 108c is electrically coupled to ground line 114a. The gate of transistor 108c is electrically coupled to word line 110a.

Phase change memory cell 104d includes phase change element 106d and transistor 108d. One side of phase change element 106d is electrically coupled to bit line 112b through the line of phase change material running along bit line 112b, and the other side of phase change element 106d is electrically coupled to one side of the source-drain path of transistor 108d. The other side of the source-drain path of transistor 108d is electrically coupled to ground line 114b. The gate of transistor 108d is electrically coupled to word line 110b.

Each phase change element 106 and line of phase change material comprises a phase change material that may be made up of a variety of materials in accordance with the present invention. Generally, chalcogenide alloys that contain one or more elements from group VI of the periodic table are useful as such materials. In one embodiment, the phase change material is made up of a chalcogenide compound material, such as GeSbTe, SbTe, GeTe, or AgInSbTe. In another embodiment, the phase change material is chalcogen free, such as GeSb, GaSb, InSb, or GeGaInSb. In other embodiments, the phase change material is made up of any suitable material including one or more of the elements Ge, Sb, Te, Ga, As, In, Se, and S.

During a set operation of phase change memory cell 104a, a set current or voltage pulse is selectively enabled and sent through bit line 112a and the line of phase change material to phase change element 106a thereby heating phase change element 106a above its crystallization temperature (but usually below its melting temperature) with word line 110a selected to activate transistor 108a. In this way, phase change element 106a reaches its crystalline state during this set operation. During a reset operation of phase change memory cell 104a, a reset current or voltage pulse is selectively enabled and sent through bit line 112a and the line of phase change material to phase change element 106a. The reset current or voltage quickly heats phase change element 106a above its melting temperature. After the current or voltage pulse is turned off, the phase change element 106a quickly quench cools into the amorphous state. Phase change memory cells 104b-104d and other phase change memory cells 104 in memory array 100 are set and reset similarly to phase change memory cell 104a using a similar current or voltage pulse.

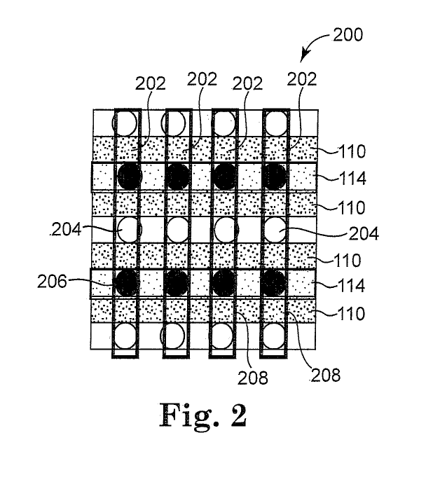

FIG. 2 illustrates a top view of one embodiment of an array of phase change memory cells 200. Array of phase change memory cells 200 includes bit lines and phase change material lines indicated at 202, ground lines 114, and word lines 110. Memory cells are electrically coupled to bit lines and phase change material lines 202 through contacts 204. Memory cells are electrically coupled to ground lines 114 through contacts 206. Word lines 110 are straight lines and bit lines and phase change material lines 202 are straight lines. Bit lines and phase change material lines 202 are perpendicular to word lines 110. Ground lines 114 run parallel to and between word lines 110.

Array of phase change memory cells 200 includes dual gate phase change memory cells. Array of phase change memory cells 200 has a cell size down to 8F², where F is the minimum feature size. Bit lines and phase change material lines 202 are electrically coupled to one side of the phase change memory elements. The other sides of the phase change memory elements are electrically coupled to one side of the source-drain paths of the transistors through contacts 204. Word lines 110 are coupled to the gates of the transistors. The other sides of the source-drain paths of the transistors are electrically coupled to ground lines 114 through contacts 206. Each contact 206 is shared by two transistors for accessing two phase change memory elements. In one embodiment, ground lines 114 are below bit lines and phase change material lines 202. In another embodiment, bit lines and phase change material lines 202 are below ground lines 114.

The active areas of transistors within array of phase change memory cells 200 are indicated at 208. Contacts 204 and 206 are aligned along bit lines and phase change material lines 202. Likewise, the active areas 208 of transistors within array of phase change memory cells 200 are also aligned with bit lines and phase change material lines 202.

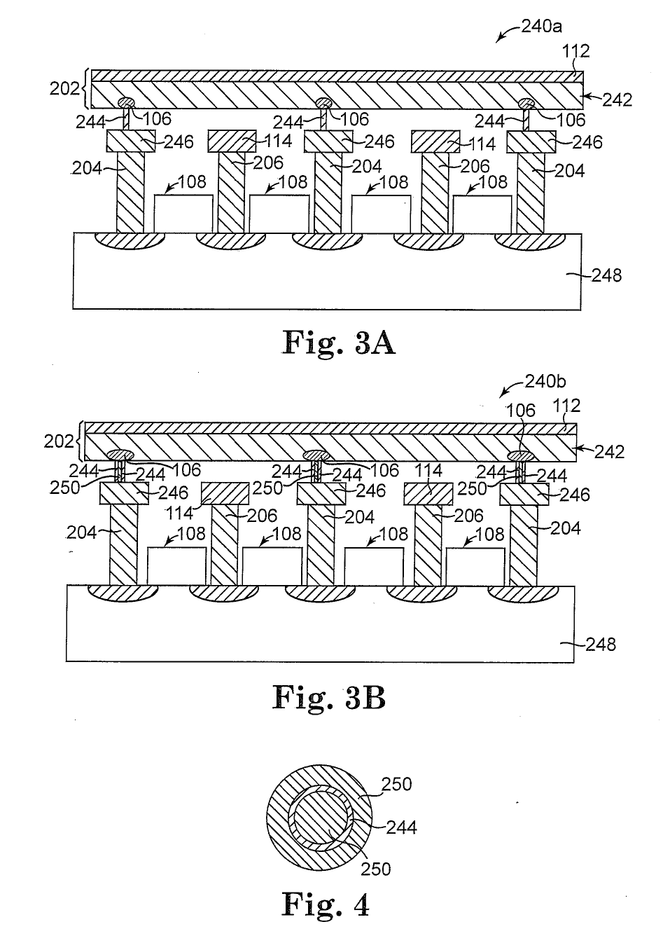

FIG. 3A illustrates a simplified side view of one embodiment of an array of mushroom phase change memory cells 240a. In one embodiment, array of phase change memory cells 240a is similar to array of phase change memory cells 100 (FIG. 1). Array 240a includes substrate 248, bit lines and phase change material lines 202, ground lines 114, transistors 108, contacts 204, contacts 206, electrodes 246, heater contacts 244, and phase change elements 106. Each bit line and phase change material line 202 includes a bit line 112 and a phase change material line 242. Phase change elements 106 are part of phase change material lines 242. Bit lines 112 and ground lines 114 are in separate metallization layers. In one embodiment, bit lines 112 comprise W or another suitable metal and are in a lower metallization layer than ground lines 114, which comprise Al, Cu, or another suitable metal. In another embodiment, bit lines 112 comprise Al, Cu, or another suitable metal and are in a higher metallization layer than ground lines 114, which comprise W or another suitable metal.

In one embodiment, bit lines 112 are perpendicular to ground lines 114. One side of the source-drain path of each transistor 108 is electrically coupled to a ground line 114 through a contact 206, which comprises Cu, W, or another suitable electrically conductive material. The other side of the source-drain path of each transistor 108 is electrically coupled to an electrode 246 through a contact 204, which comprises Cu, W, or another suitable electrically conductive material. Each electrode 246 is electrically coupled to a heater contact 244. In one embodiment, each heater contact 244 has a sublithographic cross-section. Each heater contact 244 contacts a phase change element 106 to form a mushroom memory cell. The gate of each transistor 108 is electrically coupled to a word line 110, which comprises doped poly-Si, W, TiN, NiSi, CoSi, TiSi, WSiX, or another suitable material.

During fabrication of array of phase change memory cells 240a, phase change material is deposited over heater contacts 244. The phase change material is then etched using line lithography to form phase change material lines 242. In another embodiment, conductive material is deposited over the phase change material and the conductive material and the phase change material are etched at the same time to form bits lines 112 and phase change material lines 242. In either embodiment, individual etching of each phase change element 106 and thus edge damage due to the etching is avoided.

FIG. 3B illustrates a simplified side view of another embodiment of an array of phase change memory cells 240b. Array of phase change memory cells 240b is similar to array of phase change memory cells 240a previously described and illustrated with reference to FIG. 3A, except that array of phase change memory cells 240b includes ring contact memory cells in place of mushroom memory cells. Each ring contact includes a cylindrical core of insulation material 250 surrounded by a circular heater contact 244.

FIG. 4A illustrates a top cross-sectional view of one embodiment of a ring contact. Each ring contact includes a cylindrical core of insulation material 250. The cylindrical core of insulation material is surrounded by a ring of heater contact material 244. The ring of heater contact material 244 is surrounded by additional insulation material 250.

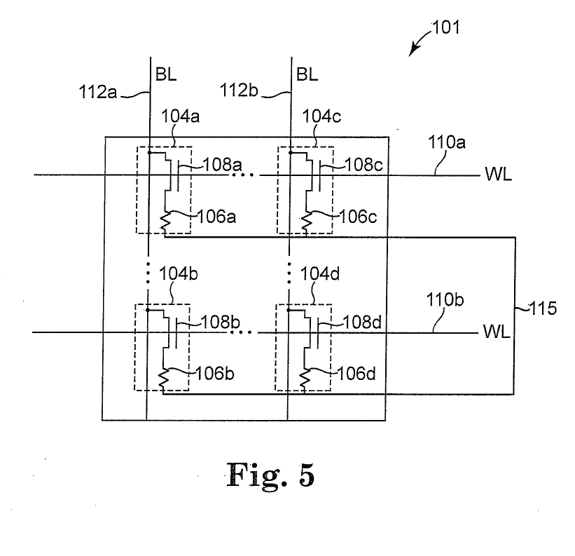

FIG. 5 is a diagram illustrating another embodiment of an array of phase change memory cells 101. Memory array 101 includes phase change memory cells 104a-104d, bit lines 112a-112b, word lines 110a-110b, and a common or ground plate 115. Memory array 101 also includes a plate of phase change material aligned with and contacting common or ground plate 115.

Each phase change memory cell 104 is electrically coupled to a word line 110, a bit line 112, and common or ground plate 115. For example, phase change memory cell 104a is electrically coupled to bit line 112a, word line 110a, and common or ground plate 115, and phase change memory cell 104b is electrically coupled to bit line 112a, word line 110b, and common or ground plate 115. Phase change memory cell 104c is electrically coupled to bit line 112b, word line 110a, and common or ground plate 115, and phase change memory cell 104d is electrically coupled to bit line 112b, word line 110b, and common or ground plate 115.

Each phase change memory cell 104 includes a phase change element 106 and a transistor 108. Phase change memory cell 104a includes phase change element 106a and transistor 108a. One side of phase change element 106a is electrically coupled to common or ground plate 115 through the plate of phase change material, and the other side of phase change element 106a is electrically coupled to one side of the source-drain path of transistor 108a. The other side of the source-drain path of transistor 108a is electrically coupled to bit line 112a. The gate of transistor 108a is electrically coupled to word line 110a. Phase change memory cell 104b includes phase change element 106b and transistor 108b. One side of phase change element 106b is electrically coupled to common or ground plate 115 through the plate of phase change material, and the other side of phase change element 106b is electrically coupled to one side of the source-drain path of transistor 108b. The other side of the source-drain path of transistor 1108b is electrically coupled to bit line 112a. The gate of transistor 108b is electrically coupled to word line 110b.

Phase change memory cell 104c includes phase change element 106c and transistor 108c. One side of phase change element 106c is electrically coupled to common or ground plate 115 through the plate of phase change material, and the other side of phase change element 106c is electrically coupled to one side of the source-drain path of transistor 108c. The other side of the source-drain path of transistor 108c is electrically coupled to bit line 112b. The gate of transistor 108c is electrically coupled to word line 110a. Phase change memory cell 104d includes phase change element 106d and transistor 108d. One side of phase change element 106d is electrically coupled to common or ground plate 115 through the plate of phase change material, and the other side of phase change element 106d is electrically coupled to one side of the source-drain path of transistor 108d. The other side of the source-drain path of transistor 108d is electrically coupled to bit line 112b. The gate of transistor 108d is electrically coupled to word line 110b.

In operation of one embodiment during a write operation of phase change memory cell 104a, a ground potential is applied to common or ground plate 115, and word line 110a is selected to activate transistor 108a. A negative programming voltage is applied to bit line 112a while bit line 112b and the other unselected bit lines 112 in memory array 101 are connected to ground or allowed to float. In one embodiment during a read operation of phase change memory cell 104a, a ground potential is applied to common or ground plate 115, and word line 110a is selected to activate transistor 108a. A positive or negative read voltage is applied to bit line 112a while bit line 112b and the other unselected bit lines 112 in memory array 101 are connected to ground. With the read voltage applied to bit line 112a, the current through phase change element 106a on bit line 112a is sensed to determine the state of phase change element 106a.

In operation of another embodiment during a write operation of phase change memory cell 104a, a positive supply voltage (V_{dd}) is applied to common or ground plate 115, and word line 110a is selected to activate transistor 108a. A zero volts programming voltage is applied to bit line 112a while bit line 112b and the other unselected bit lines 112 in memory array 101 are connected to V_{dd}. In another embodiment during a read operation of phase change memory cell 104a, V_{dd} is applied to common or ground plate 115, and word line 110a is selected to activate transistor 108a. A positive read voltage is applied to bit line 112a while bit line 112b and the other unselected bit lines 112 in memory array 101 are connected to V_{dd}. With the read voltage applied to bit line 112a, the current through phase change element 106a on bit line 112a is sensed to determine the state of phase change element 106a.

In operation of another embodiment during a write operation of phase change memory cell 104a, a ground potential is applied to common or ground plate 115, and word line 110a is selected to activate transistor 108a. A V_{dd} programming voltage is applied to bit line 112a while bit line 112b and the other unselected bit lines 112 in memory array 101 are connected to ground or allowed to float. In another embodiment during a read operation of phase change memory cell 104a, a ground potential is applied to common or ground plate 115, and word line 110a is selected to activate transistor 108a. A positive or negative read voltage is applied to bit line 112a while bit line 112b and the other unselected bit lines 112 in memory array 101 are connected to V_{dd}. With the read voltage applied to bit line 112a, the current through phase change element 106a on bit line 112a is sensed to determine the state of phase change element 106a.

In operation of another embodiment during a write operation of phase change memory cell 104a, V_{dd}/2 or other suitable fraction f is applied to common or ground plate 115, and word line 110a is selected to activate transistor 108a. A −V_{dd}/2 or corresponding f−1 programming voltage is applied to bit line 112a while bit line 112b and the other unselected bit lines 112 in memory array 101 are connected to V_{dd}/2 or f. In another embodiment during a read operation of phase change memory cell 104a, V_{dd}/2 or other suitable fraction f is applied to common or ground plate 115, and word line 110a is selected to activate transistor 108a. A positive or negative read voltage is applied to bit line 112a while bit line 112b and the other unselected bit lines 112 in memory array 101 are connected to V_{dd}/2 or f. With the read voltage applied to bit line 112a, the current through phase change element 106a on bit line 112a is sensed to determine the state of phase change element 106a. Phase change memory cells 104b-104d and other phase change memory cells 104 in memory array 101 are read and written similarly to phase change memory cell 104a using similar read and write operations.

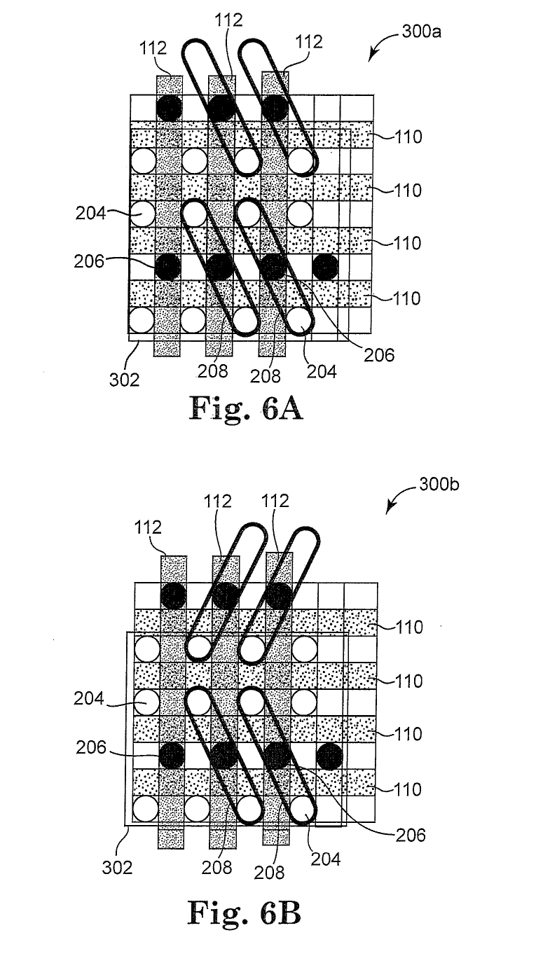

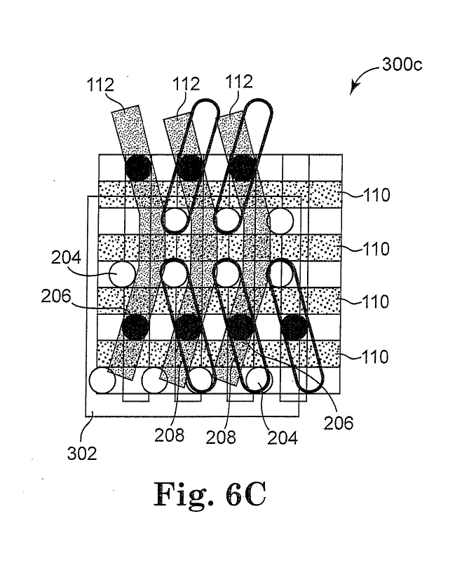

FIG. 6A illustrates a top view of one embodiment of an array of phase change memory cells 300a including a conductive plate and a plate of phase change material as indicated at 302. The conductive plate contacts and is on top of the plate of phase change material. Array of phase change memory cells 300a includes bit lines 112, the conductive plate and plate of phase change material 302, and word lines 110. Memory cells are electrically coupled to the conductive plate and plate of phase change material 302 through contacts 204. Memory cells are electrically coupled to bit lines 112 through contacts 206. Word lines 110 are perpendicular to bit lines 112.

Array of phase change memory cells 300a includes single gate phase change memory cells. Array of phase change memory cells 300a has a cell size down to 6F², where F is the minimum feature size. In other embodiments, wider transistors are used such that the distance between contacts 204 is increased. Bit lines 112 are electrically coupled to one side of the source-drain paths of transistors through contacts 206. Each contact 206 is shared by two transistors for accessing two phase change memory elements. Word lines 110 are electrically coupled to the gates of the transistors. The other sides of the source-drain paths of the transistors are electrically coupled to one side of the phase change memory elements through contacts 204. The other sides of the phase change memory elements are electrically coupled to the plate of phase change material. In one embodiment, the conductive plate and plate of phase change material 302 are above bit lines 112.

The active areas of transistors within array of phase change memory cells 300a are indicated at 208. Active areas 208 are configured diagonally across array of phase change memory cells 300a from an upper left contact 204 to a lower right contact 204. Active areas 208 run from one contact 204 across a first word line 110 to a bit line 112, and from the bit line 112 across a second word line 110 to a second contact 204.

FIG. 6B illustrates a top view of another embodiment of an array of phase change memory cells 300b including a conductive plate and plate of phase change material as indicated at 302. Array of phase change memory cells 300b is similar to array of phase change memory cells 300a previously described and illustrated with reference to FIG. 6A, except that in array of phase change memory cells 300b active areas 208 are configured in alternating diagonal directions across the array. Active areas 208 alternate between running from an upper right contact 204 to a lower left contact 204 and from an upper left contact 204 to a lower right contact 204.

FIG. 6C illustrates a top view of another embodiment of an array of phase change memory cells 300c including a conductive plate and plate of phase change material as indicated at 302. Array of phase change memory cells 300c is similar to array of phase change memory cells 300b previously described and illustrated with reference to FIG. 6B, except that in array of phase change memory cells 300c bit lines 112 are not straight lines. Bit lines 112 zigzag across array of phase change memory cells 300c between contacts 204.

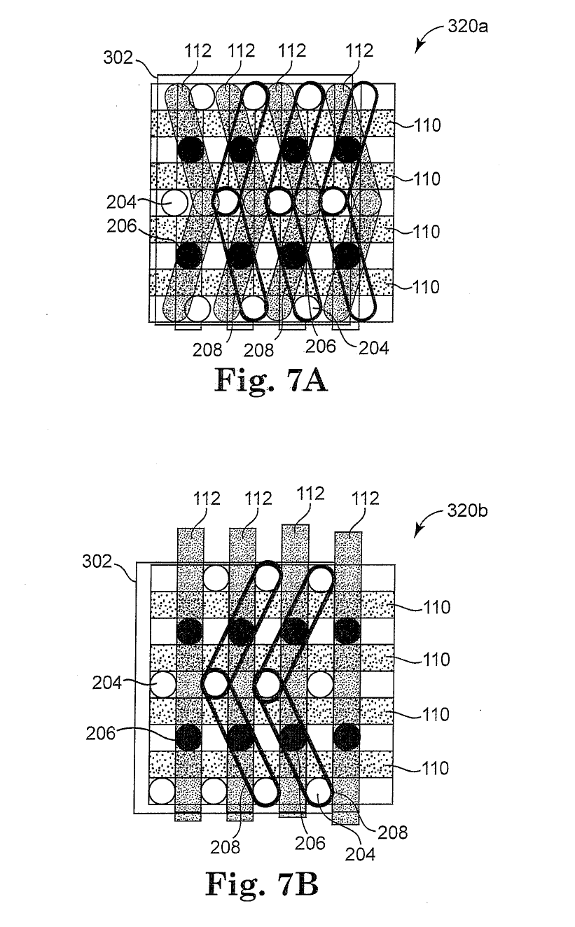

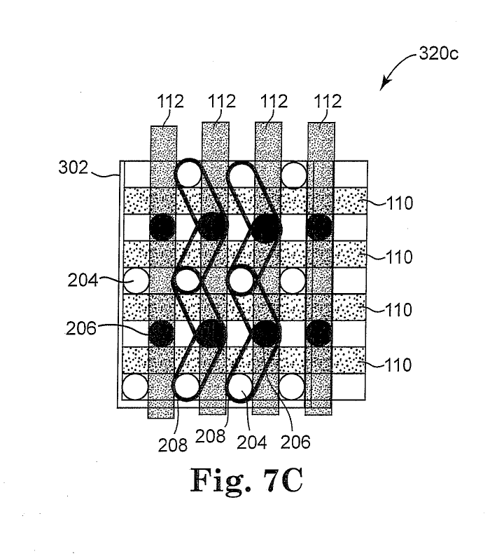

FIG. 7A illustrates a top view of another embodiment of an array of phase change memory cells 320a including a conductive plate and plate of phase change material as indicated at 302. Array of phase change memory cells 320a includes bit lines 112, the conductive plate and plate of phase change material 302, and word lines 110. Memory cells are electrically coupled to the conductive plate and plate of phase change material 302 through contacts 204. Memory cells are electrically coupled to bit lines 112 through contacts 206. Word lines 110 are straight lines and bit lines 112 are not straight lines. Bit lines 112 zigzag across the array of phase change memory cells between contacts 204.

Array of phase change memory cells 320a includes dual gate phase change memory cells. Array of phase change memory cells 320a has a cell size down to 8F², where F is the minimum feature size. Bit lines 112 are electrically coupled to one side of the source-drain paths of the transistors through contacts 206. Each contact 206 is shared by two transistors for accessing two phase change memory elements. Word lines 110 are electrically coupled to the gates of the transistors. The other sides of the source-drain paths of the transistors are electrically coupled to one side of phase change memory elements through contacts 204. The other sides of the phase change memory elements are electrically coupled to the plate of phase change material. In one embodiment, the conductive plate and plate of phase change material 302 are above bit lines 112.

The active areas of transistors within array of phase change memory cells 320a are indicated at 208. Active areas 208 are configured in alternating diagonal directions across array of phase change memory cells 320a. Active areas 208 alternate between running from an upper right contact 204 to a lower left contact 204 and from the upper left contact 204 to a lower right contact 204. Active areas 208 run from one contact 204 across a first word line 110 to a bit line 112, and from the bit line 112 across a second word line 110 to a second contact 204.

FIG. 7B illustrates a top view of another embodiment of an array of phase change memory cells 320b including a conductive plate and plate of phase change material as indicated at 302. Array of phase change memory cells 320b is similar to array of phase change memory cells 320a previously described and illustrated with reference to FIG. 7A, except that in array of phase change memory cells 320b bit lines 112 are straight lines and are substantially perpendicular to word lines 110.

FIG. 7C illustrates a top view of another embodiment of an array of phase change memory cells 320c including a conductive plate and plate of phase change material as indicated at 302. Array of phase change memory cells 320c is similar to array of phase change memory cells 320b previously described and illustrated with reference to FIG. 7B, except that in array of phase change memory cells 320c active areas 208 alternate direction at each phase change element. Active areas 208 zigzag across array of phase change memory cells 320c along each bit line 112.

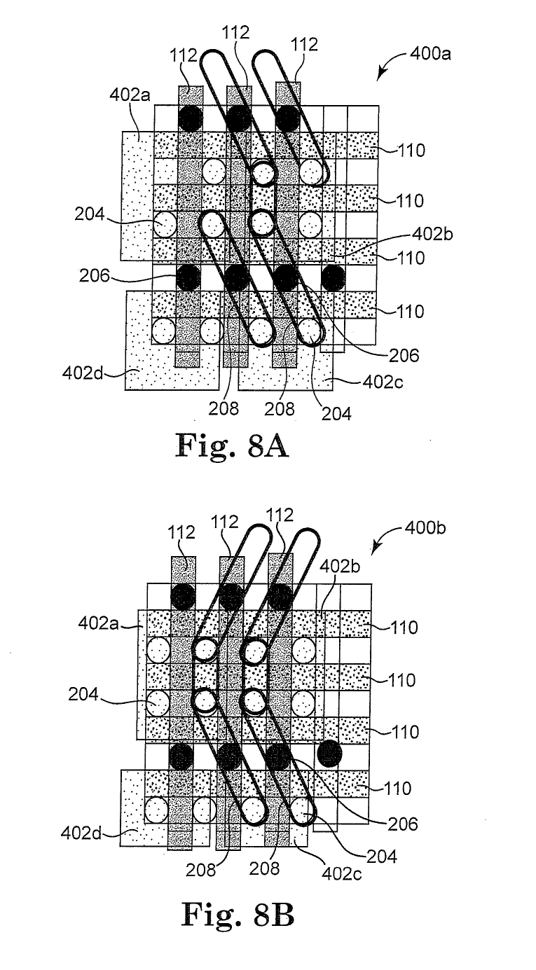

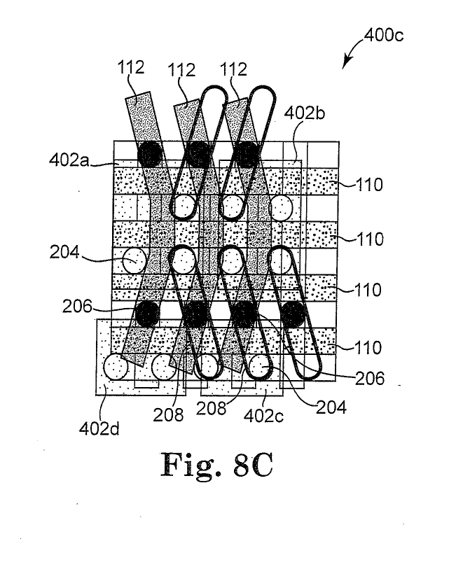

FIG. 8A illustrates a top view of one embodiment of an array of phase change memory cells 400a including several mini-plates of conductive material and phase change material as indicated at 402a-402d. Each conductive mini-plate contacts and is on top of each mini-plate of phase change material. Array of phase change memory cells 400a is similar to array of phase change memory cells 300a previously described and illustrated with reference to FIG. 6A, except that in array of phase change memory cells 400a, the conductive plate and plate of phase change material 302 is replaced with mini-plates 402a-402d. Each mini-plate 402a-402d provides 4, 8, 16, 32, 64, 128, or other suitable number of phase change elements. In one embodiment, mini-plates 402a-402d reduce the power consumption of array of phase change memory cells 400a as compared to array of phase change memory cells 300a by reducing the current used to charge a plate during read and write operations.

FIG. 8B illustrates a top view of another embodiment of an array of phase change memory cells 400b including several mini-plates of conductive material and phase change material as indicated at 402a-402d. Each conductive mini-plate contacts and is on top of each mini-plate of phase change material. Array of phase change memory cells 400b is similar to array of phase change memory cells 300b previously described and illustrated with reference to FIG. 6B, except that in array of phase change memory cells 400b, the conductive plate and plate of phase change material 302 is replaced with mini-plates 402a-402d. Each mini-plate 402a-402d provides 4, 8, 16, 32, 64, 128, or other suitable number of phase change elements. In one embodiment, mini-plates 402a-402d reduce the power consumption of array of phase change memory cells 400b as compared to array of phase change memory cells 300b by reducing the current used to charge a plate during read and write operations.

FIG. 8C illustrates a top view of another embodiment of an array of phase change memory cells 400c including several mini-plates of conductive material and phase change material as indicated at 402a-402d. Each conductive mini-plate contacts and is on top of each mini-plate of phase change material. Array of phase change memory cells 400c is similar to array of phase change memory cells 300c previously described and illustrated with reference to FIG. 6C, except that in array of phase change memory cells 400c, the conductive plate and plate of phase change material 302 is replaced with mini-plates 402a-402d. Each mini-plate 402a-402d provides 4, 8, 16, 32, 64, 128, or other suitable number of phase change elements. In one embodiment, mini-plates 402a-402d reduce the power consumption of array of phase change memory cells 400c as compared to array of phase change memory cells 300c by reducing the current used to charge a plate during read and write operations.

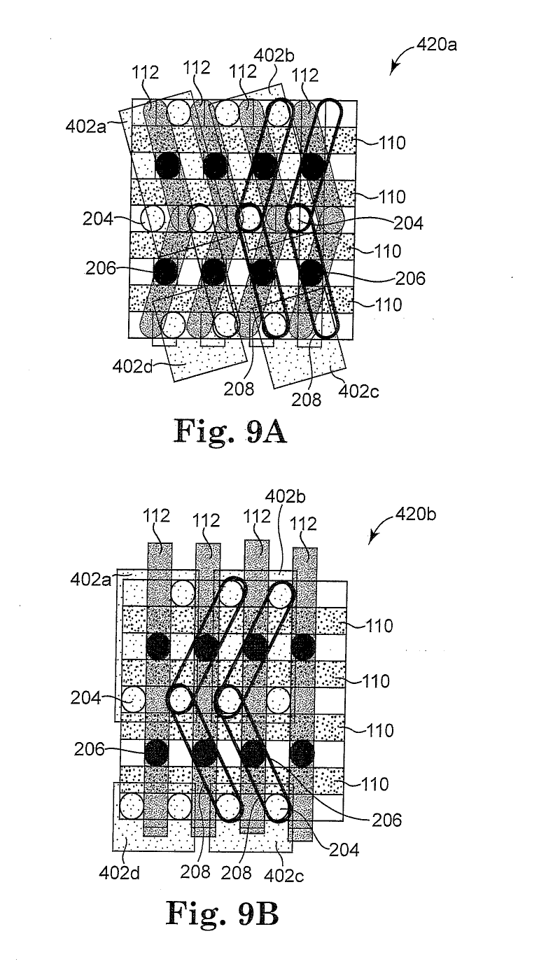

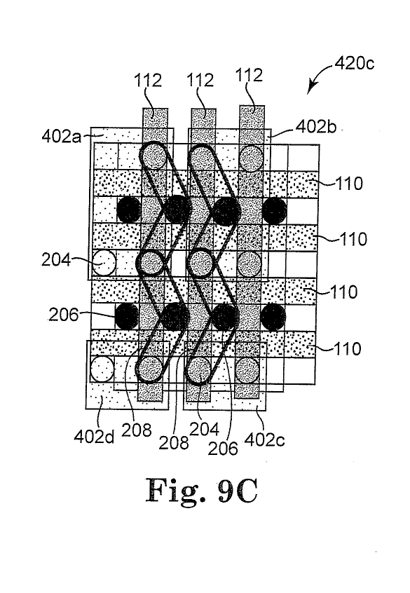

FIG. 9A illustrates a top view of another embodiment of an array of phase change memory cells 420a including several mini-plates of conductive material and phase change material as indicated at 402a-402d. Each conductive mini-plate contacts and is on top of each mini-plate of phase change material. Array of phase change memory cells 420a is similar to array of phase change memory cells 320a previously described and illustrated with reference to FIG. 7A, except that in array of phase change memory cells 420a, the conductive plate and plate of phase change material 302 is replaced with mini-plates 402a-402d. Each mini-plate 402a-402d provides 4, 8, 16, 32, 64, 128, or other suitable number of phase change elements. In one embodiment, mini-plates 402a-402d reduce the power consumption of array of phase change memory cells 420a as compared to array of phase change memory cells 320a by reducing the current used to charge a plate during read and write operations.

FIG. 9B illustrates a top view of another embodiment of an array of phase change memory cells 420b including several mini-plates of conductive material and phase change material as indicated at 402a-402d. Each conductive mini-plate contacts and is on top of each mini-plate of phase change material. Array of phase change memory cells 420b is similar to array of phase change memory cells 320b previously described and illustrated with reference to FIG. 8B, except that in array of phase change memory cells 420b, the conductive plate and plate of phase change material 302 is replaced with mini-plates 402a-402d. Each mini-plate 402a-402d provides 4, 8, 16, 32, 64, 128, or other suitable number of phase change elements. In one embodiment, mini-plates 402a-402d reduce the power consumption of array of phase change memory cells 420b as compared to array of phase change memory cells 320b by reducing the current used to charge a plate during read and write operations.

FIG. 9C illustrates a top view of another embodiment of an array of phase change memory cells 420c including several mini-plates of conductive material and phase change material as indicated at 402a-402d. Each conductive mini-plate contacts and is on top of each mini-plate of phase change material. Array of phase change memory cells 420c is similar to array of phase change memory cells 320c previously described and illustrated with reference to FIG. 7C, except that in array of phase change memory cells 420c, the conductive plate and plate of phase change material 302 is replaced with mini-plates 402a-402d. Each mini-plate 402a-402d provides 4, 8, 16, 32, 64, 128, or other suitable number of phase change elements. In one embodiment, mini-plates 402a-402d reduce the power consumption of array of phase change memory cells 420c as compared to array of phase change memory cells 320c by reducing the current used to charge a plate during read and write operations.

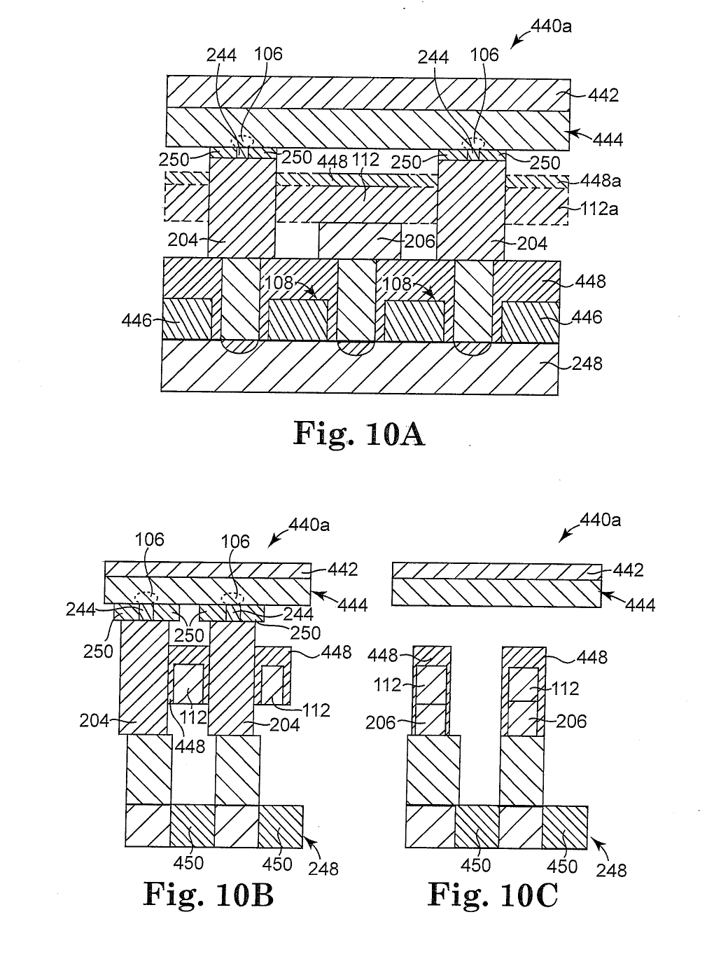

FIG. 10A illustrates a simplified side view of one embodiment of an array of phase change memory cells 440a including a conductive plate 442 and a plate of phase change material 444. FIG. 10A is taken diagonally along an active area 208 (FIG. 6A) and to a contact 204 in the same column with a contact 204 that is part of active area 208. FIG. 10B illustrates a simplified side view of one embodiment of array of phase change memory cells 440a through a phase change element 106, and FIG. 10C illustrates another simplified side view of one embodiment of array of phase change memory cells 440a through a bit line 112. In one embodiment, conductive plate 442 and plate of phase change material 444 are similar to the conductive plate and plate of phase change material 302 described and illustrated with reference to FIGS. 6A-7C. In another embodiment, conductive plate 442 and plate of phase change material 440 are similar to the mini-plates 402 described and illustrated with reference to FIGS. 8A-9C.

Array of phase change memory cells 440a includes substrate 248 including shallow trench isolation (STI) 450, transistors 108, isolation gates 446, conductive plate 442, phase change material plate 444 including phase change elements 106, insulation material 250, heater contacts 244, phase change element contacts 204, bit line contacts 206, bit lines 112, and dielectric material 448. Dielectric material 448a and bit line 112a are part of dielectric material 448 and bit line 112 but are located behind phase change element contacts 204.

Transistors 108 for selecting phase change elements 106 are formed on substrate 248. The gates of transistors 108 are electrically coupled to word lines 110. Isolation gates 446 are formed on substrate 248 between transistors 108. Dielectric material 448 is deposited over transistors 108 and isolation gates 406. In one embodiment, dielectric material 448, which caps bit lines 112, includes SiN or another suitable material. Phase change element contacts 204 electrically couple one side of the source-drain path of each transistor 108 to a heater contact 244. Each heater contact 244 contacts a phase change element 106 within phase change material plate 444. Insulation material 250 laterally surrounds heater contacts 244. Each bit line contact 206 electrically couples the other side of the source-drain path of each transistor 108 to a bit line 112. Plate of phase change material 444 contacts conductive plate 442.

During fabrication of array of phase change memory cells 440a, phase change material is deposited over an insulation material 250 and heater contacts 244. A phase change element 106 is formed at each intersection of the phase change material and a heater contact 244. The plate of phase change material is optionally etched to form mini-plates of phase change material. In another embodiment, a conductive material is deposited over the plate of phase change material and the conductive plate and the plate of phase change material are both optionally etched to form mini-plates of conductive material and phase change material. In either embodiment, individual etching of each phase change element 106 and thus edge damage due to the etching is avoided.

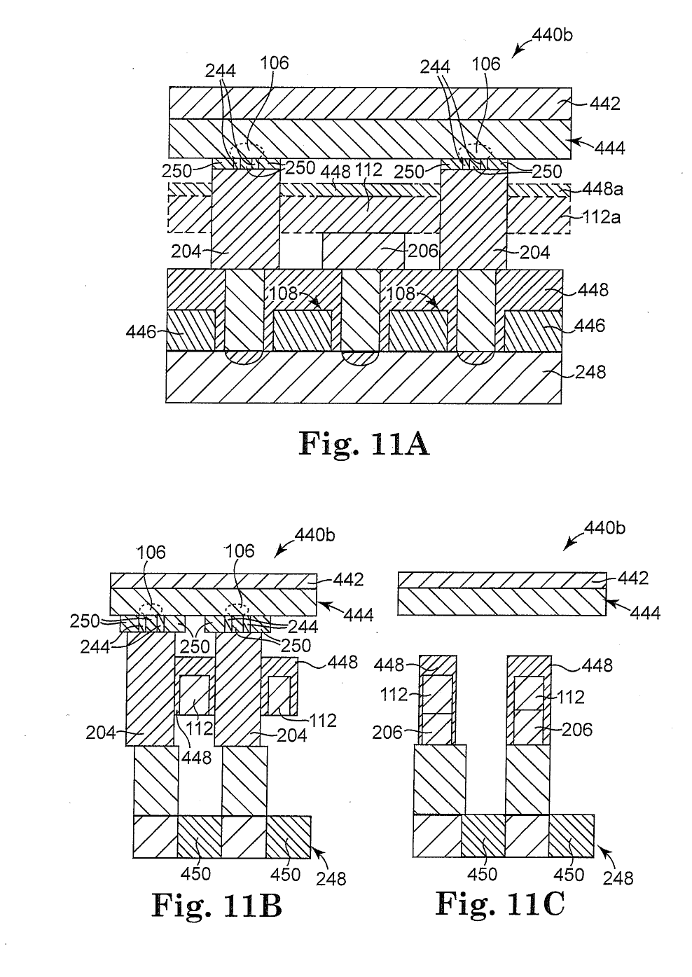

FIG. 11A illustrates a simplified side view of another embodiment of an array of phase change memory cells 440b including a conductive plate 442 and a plate of phase change material 444. FIG. 11A is taken diagonally along an active area 208 (FIG. 6A) and to a contact 204 in the same column with a contact 204 that is part of active area 208. FIG. 11B illustrates a simplified side view of one embodiment of array of phase change memory cells 440b through a phase change element 106, and FIG. 11C illustrates another simplified side view of one embodiment of array of phase change memory cells 440b through a bit line 112. Array of phase change memory cells 440b is similar to array of phase change memory cells 440a previously described and illustrated with reference to FIGS. 10A-10C, except that in array of phase change memory cells 440b the mushroom memory cells are replaced with ring contact memory cells. A phase change element 106 is formed at each intersection of the phase change material and a ring contact 244.

Embodiments of the present invention provide a phase change memory in which etching of phase change material to form individual phase change elements is avoided. More than two memory cells in the phase change memory share a common deposit of phase change material. The common deposit of phase change material may include a line of phase change material running along each bit line, a plate of phase change material covering the entire array of memory cells, or mini-plates of phase change material covering portions of the array of memory cells.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit comprising:
a bit line;
a plurality of access devices coupled to the bit line;
a plate of phase change material; and
a plurality of contacts, each contact coupled to an access device and contacting the plate of phase change material,
wherein a phase change element is formed at each intersection of a contact and the plate of phase change material.

2. The integrated circuit of claim 1, wherein each contact has a sublithographic cross-section.

3. The integrated circuit of claim 1, wherein each contact comprises a ring contact.

4. The integrated circuit of claim 1, wherein each contact and phase change element form a mushroom memory cell.

5. The integrated circuit of claim 1, wherein each contact comprises a heater contact.

6. The integrated circuit of claim 1, wherein the plate of phase change material comprises at least one of Ge, Sb, Te, Ga, As, In, Se, and S.

7. A memory comprising:
a bit line;
a first portion of phase change material coupled to the bit line; and
at least three contacts, each contact contacting the first portion of phase change material,
wherein a phase change element is formed at each intersection of a contact and the first portion of phase change material.

8. The memory of claim 7, wherein each contact has a sublithographic cross-section.

9. The memory of claim 7, wherein each contact comprises a ring contact.

10. The memory of claim 7, wherein each contact and phase change element form a mushroom memory cell.

11. The memory of claim 7, wherein each contact comprises a heater contact.

12. A memory comprising:
a bit line;
a line of phase change material contacting the bit line; and
a plurality of contacts contacting the line of phase change material,
wherein a phase change element is formed at each intersection of a contact and the line of phase change material.

13. The memory of claim 12, wherein each contact has a sublithographic cross-section.

14. The memory of claim 12, wherein each contact comprises a ring contact.

15. The memory of claim 12, wherein each contact and phase change element form a mushroom memory cell.

16. The memory of claim 12, wherein each contact comprises a heater contact.

17. The memory of claim 12, wherein the line of phase change material comprises at least one of Ge, Sb, Te, Ga, As, In, Se, and S.

18. A method for fabricating a memory, the method comprising:
providing a plurality of contacts;
depositing phase change material over the contacts; and
etching the phase change material to form lines of phase change material contacting the contacts.

19. The method of claim 18, wherein providing the contacts comprises providing ring contacts.

20. The method of claim 18, wherein providing the contacts comprises providing contacts having sublithographic cross-sections.

21. The method of claim 18, further comprising:
providing bit lines aligned with and contacting the lines of phase change material.

22. The method of claim 18, wherein etching the phase change material comprises etching the phase change material to form straight lines of phase change material.

23. The method of claim 18, wherein etching the phase change material comprises etching the phase change material to form zigzagging lines of phase change material.

24. A method for fabricating a memory, the method comprising:
providing a plurality of contacts;
depositing a plate of phase change material over the contacts to form phase change elements at the intersections of the contacts and the plate of phase change material; and
depositing a plate of conductive material over the plate of phase change material.

25. The method of claim 24, wherein providing the contacts comprises providing ring contacts.

26. The method of claim 24, wherein providing the contacts comprises providing contacts having sublithographic cross-sections.

27. The method of claim 24, further comprising:
etching the plate of conductive material and the plate of phase change material to form mini-plates of conductive material and phase change material.

28. The method of claim 24, further comprising:
providing a plurality of access devices, each access device coupled to a contact; and
providing a plurality of bit lines, each bit line coupled to an access device.

29. The method of claim 28, wherein providing the bit lines comprises providing straight bit lines.

30. The method of claim 28, wherein providing the bit lines comprises providing zigzagging bit lines.
